(19) United States
(12) Patent Application Publication
(10) Pub. No.: US 2019/0047420 A1
(43) Pub. Date: Feb. 14, 2019

(54) ELECTRIC POWER CONTROL DEVICE AND VEHICLE

(71) Applicant: HONDA MOTOR CO., LTD., Tokyo (JP)

(72) Inventors: Hiroaki Akimoto, Tochigi (JP); Shota Takeda, Tochigi (JP)

(21) Appl. No.: 16/084,798

(22) PCT Filed: Jan. 23, 2017
(86) PCT No.: PCT/JP2017/002085

§ 371 Date: Sep. 13, 2018

(30) Foreign Application Priority Data
Mar. 18, 2016 (JP) 2016-055919

(51) Int. Cl. B60L 11/00; B60L 11/18; H02P 27/06; H02M 3/155; H02M 7/797; G01R 19/165

(52) U.S. Cl. CPC B60L 11/005; B60L 11/1803; H02P 27/06; H02M 2001/007; H02M 7/797; G01R 19/16528; B60L 2240/547; H02M 3/155

(57) ABSTRACT

Provided area device and the like which make it possible to prolong the operation duration time of a load using a capacitor as a main power supply. If a capacitor voltage V₁ is equal to or higher than a first reference voltage Vₜₕ₁, then electric power that has not undergone a step-up operation by a converter (12) is supplied from a capacitor (11) to an electric motor (14), which is a load. Meanwhile, if the discharge capacitance of the capacitor (11) decreases due to the supply of electric power to the electric motor (14), which is the load, causing the capacitor voltage V₁ to decrease to become lower than the first reference voltage Vₜₕ₁, then electric power that has undergone the step-up operation by the converter (12) is supplied to the load from the capacitor (11).

### TECHNICAL FIELD

The present invention relates to a technique for controlling electric power supplied to a load, such as an electric motor, from a power supply, such as a capacitor.

### BACKGROUND ART

Secondary batteries are extensively used as the drive power supplies of vehicles, such as electric carrier vehicles (refer to Patent Literature 1). However, secondary batteries pose a problem, such as the need for frequent replacement due to the deterioration of their electrochemical performance. A possible solution is, therefore, to use, as the power supplies for the vehicles and the like, capacitors, which are more resistant to deterioration in performance and last longer than secondary batteries.

### CITATION LIST

### Patent Literature

Patent Literature 1: Japanese Patent Application Laid-Open No. 2009-012508

### SUMMARY OF INVENTION

### Technical Problem

However, capacitors have a lower energy density than secondary batteries do, so that the output voltages of capacitors decrease faster than those of the secondary batteries as the amount of discharged electricity increases, and soon decrease below a voltage that enables a load to operate. For this reason, it is difficult in some cases to use capacitors as the main power supplies of loads.

An object of the present invention, therefore, is to provide a device and the like that enable an improved rate of utilization so as to achieve a longer operation duration time of a load that uses a capacitor as its main power supply.

### Solution to Problem

The present invention relates to an electric power control device for controlling the electric power of a capacitor in equipment provided with the capacitor, a converter, and a load electrically connected, through the converter, to the capacitor serving as a main power supply.

An electric power control device in accordance with the present invention includes: a measuring element which measures a voltage of the capacitor; a determining element which determines whether the voltage of the capacitor measured by the measuring element is equal to or higher than a reference voltage required to operate the load; and a mode control element which supplies electric power that has not undergone a step-up operation by the converter from the capacitor to the load according to a first drive mode in a case where the determining element determines that the voltage of the capacitor is equal to or higher than the reference voltage, and supplies electric power that has undergone the step-up operation by the converter from the capacitor to the load according to a second drive mode in a case where the determining element determines that the voltage of the capacitor is lower than the reference voltage.

In the electric power control device according to the present invention, preferably, the measuring element measures the regenerative voltage of an electric motor which is the load, the determining element determines whether the regenerative voltage of the electric motor measured by the measuring element is equal to or higher than the reference voltage, and the mode control element supplies regenerative electric power that has not undergone the step-up operation by the converter to the capacitor from the electric motor according to a first regenerative mode in a case where the determining element determines that the regenerative voltage of the electric motor is equal to or higher than the reference voltage, and supplies regenerative electric power that has undergone the step-up operation by the converter to the capacitor from the electric motor according to a second regenerative mode in a case where the determining element determines that the regenerative voltage of the electric motor is lower than the reference voltage.

### Effect of the Invention

According to the electric power control device in accordance with the present invention, if the voltage of a capacitor is equal to or higher than a reference voltage, then electric power that has not undergone a step-up operation by a converter is supplied to a load from the capacitor. Meanwhile, if the discharge capacitance of the capacitor decreases due to the supply of electric power to the load, causing an output voltage to decrease to be lower than the reference voltage, then electric power that has undergone the step-up operation by the converter is supplied to the load from the capacitor. Thus, the operation duration time of the load is prolonged.

Further, if the regenerative voltage of an electric motor, which is a load, is equal to or higher than the reference voltage, then the regenerative electric power that has not undergone the step-up operation by the converter is supplied from the electric motor to the capacitor. Meanwhile, if the regenerative voltage of the electric motor, which is the load, is lower than the reference voltage, then the regenerative electric power that has undergone the step-up operation by the converter is supplied from the electric motor to the capacitor. Thus, the discharge capacitance of the capacitor is increased or restored, leading to a prolonged operation duration time of the load.

### BRIEF DESCRIPTION OF DRAWINGS

FIG. 1 is a block diagram illustrating a vehicle and an electric power control device as embodiments of the present invention;

FIG. 2 is an explanatory diagram related to an electric power control method;

FIG. 3 is an explanatory diagram related to the functions of the electric power control device in a power running mode of the vehicle;

FIG. 4 is an explanatory diagram related to the functions of the electric power control device in a regenerative braking mode of the vehicle; and

FIG. 5 is an explanatory diagram related to the temporal changes in the input voltage and the output voltage of a converter.

### DESCRIPTION OF EMBODIMENTS

(Configuration)

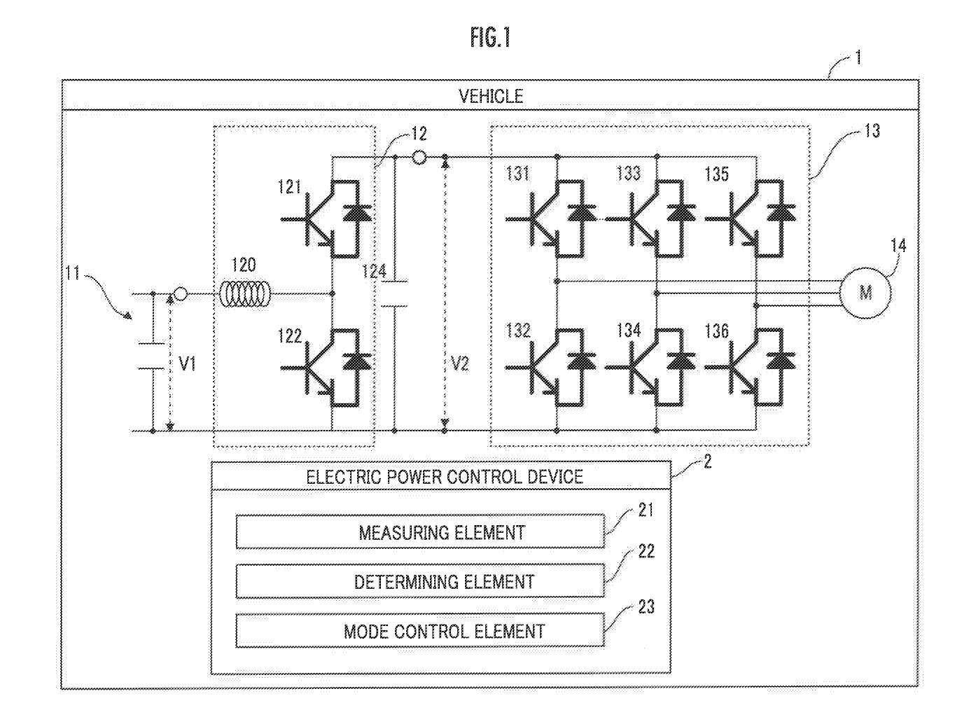

A vehicle 1 as an embodiment of the present invention illustrated in FIG. 1 includes an electric power control device 2, a capacitor 11, a converter 12, an inverter 13, and an electric motor 14 (load). The vehicle 1 uses the capacitor 11 as the main power supply thereof The main power supply may be the only power supply, or the vehicle 1 may be provided with a battery, which is connected in parallel with the capacitor 11, as an auxiliary power supply. The capacitor 11 may be, for example, an activated carbon capacitor or a lithium-ion capacitor, depending on the internal configuration thereof; however, the type of capacitor used for the capacitor 11 is not limited thereto, and any type of capacitor may be used.

The converter 12 (DC/DC converter) is connected to the capacitor 11 at one end thereof and connected to the electric motor 14 through the inverter 13 at the other end thereof A capacitor 124 is connected between the converter 12 and the inverter 13. The converter 12 includes a reactor 120 (or a coil), a step-up element 121, and a step-down element 122. The inverter 13 is connected to the electric motor 14. The inverter 13 has a plurality of sets of elements 131 to 136 (composed of FETs, IGBTs, transistors, diodes and the like) corresponding to the number of phases of the electric motor 14.

The electric power control device 2 is comprised of a computer and includes a measuring element 21, a determining element 22, and a mode control element 23. The electric power control device 2 and the elements 21 to 23 thereof are designed to carry out their arithmetic processing when, for example, an arithmetic processing unit (e.g. a CPU or a processor core) reads necessary data and software (program) from a storage unit (a memory, such as a ROM or RAM) and executes the program.

(Functions)

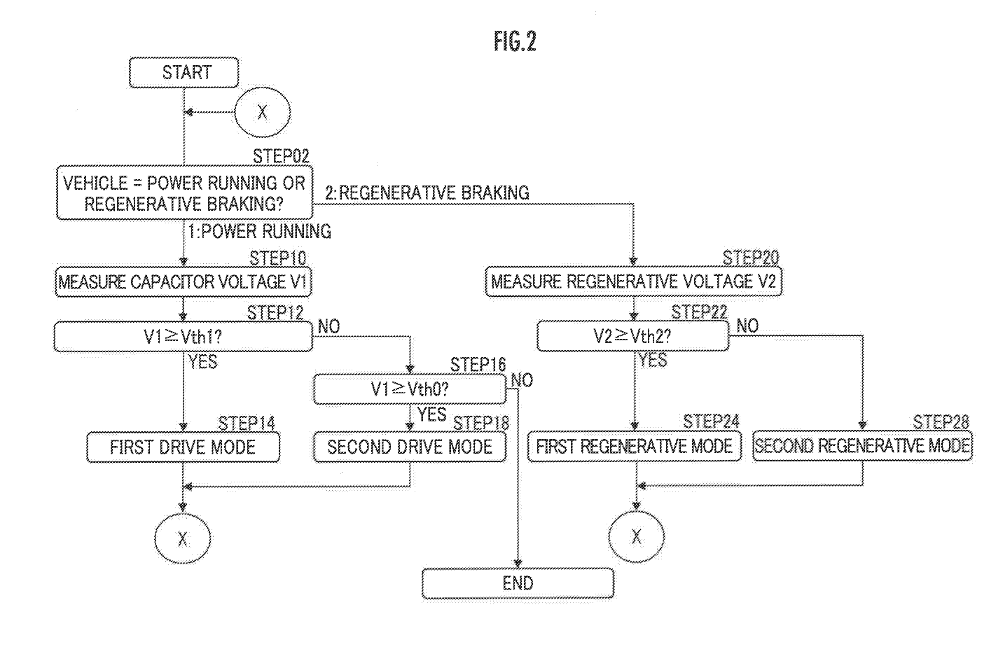

The electric power control device 2 determines whether the vehicle 1 is in a power running mode or a regenerative braking mode (STEP02 of FIG. 2). For example, it is determined that the vehicle 1 is in the power running mode if a capacitor voltage V₁ is decreasing, while it is determined that the vehicle 1 is in the regenerative braking mode if a regenerative voltage V₂ is increasing.

(Electric Power Control in the Power Running Mode)

If it is determined that the vehicle 1 is in the power running mode (1 in STEP02 of FIG. 2), then the measuring element 21 measures the voltage V₁ of the capacitor 11 (STEP10 of FIG. 2). For the measurement, an output signal from a first voltage sensor (not illustrated), which outputs signals based on the capacitor voltage V₁, is used.

The determining element 22 determines whether the capacitor voltage V₁ measured by the measuring element 21 is equal to or higher than a first reference voltage Vₜₕ₁ (STEP12 of FIG. 2). The first reference voltage Vₜₕ₁ is set to a voltage required for the electric motor 14, which is the load, to stably operate or to a value obtained by adding a slight positive value thereto.

If the determining element 22 determines that the capacitor voltage V₁ is equal to or higher than the first reference voltage Vₜₕ₁ (YES in STEP12 of FIG. 2), then the mode control element 23 supplies electric power that has not undergone a step-up operation by the converter 12 to the electric motor 14 from the capacitor 11 according to a first drive mode (STEP14 of FIG. 2). In this case, in the converter 12, the step-up element 121 is maintained ON, whereas the step-down element 122 is maintained OFF. Hence, current is supplied from the capacitor 11 to the electric motor 14 via the inverter 13 without boosting the voltage V₁ of the capacitor 11. Thus, the electric motor 14 drives wheels (not illustrated) thereby holding the vehicle 1 in the power running mode.

If the determining element 22 determines that the capacitor voltage V₁ is lower than the first reference voltage Vₜₕ₁ (NO in STEP12 of FIG. 2), then the determining element 22 further determines whether the capacitor voltage V₁ is equal to or higher than a stop voltage Vₜₕ₀, which is lower than the first reference voltage Vₜₕ₁ (STEP16 of FIG. 2).

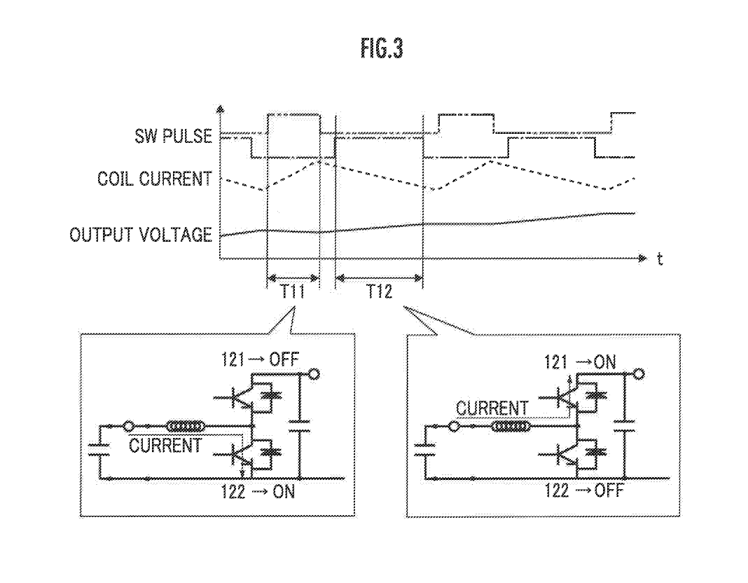

If the determining element 22 determines that the capacitor voltage V₁ equal to or higher than the stop voltage Vₜₕ₀ (YES in STEP16 of FIG. 2), then the mode control element 23 supplies the electric power that has undergone the step-up operation by the converter 12 to the electric motor 14 from the capacitor 11 according to a second drive mode (STEP18 of FIG. 2). FIG. 3 illustrates an example of how the electric power is controlled at that time. In FIG. 3, the ON/OFF of the step-up element 121 is indicated by the dot-dash line (upper: ON; and lower: OFT), the ON/OFF of the step-down element 122 is indicated by the two-dot chain line, the current passing through the reactor 120 is indicated by the dashed line, and the output voltage on the inverter 13 side is indicated by the solid line.

In a period T₁₁, the step-up element 121 is controlled to OFF and the step-down element 122 is controlled to ON, thereby increasing the current flowing into the reactor 120, so that the current energy accumulated in the reactor 120 increases. In a period T₁₂, which starts after an interval following the period T₁₁, the step-up element 121 is controlled to ON and the step-down element 122 is controlled to OFF, causing the current energy, which has been accumulated in the reactor 120, to be released. This decreases the current flowing into the reactor 120, and the output voltage of the converter 12 on the electric motor 14 side increases. The interval (dead time) between the period. T₁₁ and T₁₂ is set in order to avoid a situation in which the step-up element 121 and the step-down element 122 are both controlled to ON. The repetition of the procedure describe above leads to a gradual increase in the output voltage of the converter 12 on the inverter 13 side.

If the determining element 22 determines that the voltage V₁ of the capacitor 11 is lower than the stop voltage Vₜₕ₀ (NO in STEP16 of FIG. 2), then the mode control element 23 controls the output voltage of the converter 12 to zero so as to stop the supply of electric power from the capacitor 11 to the electric motor 14.

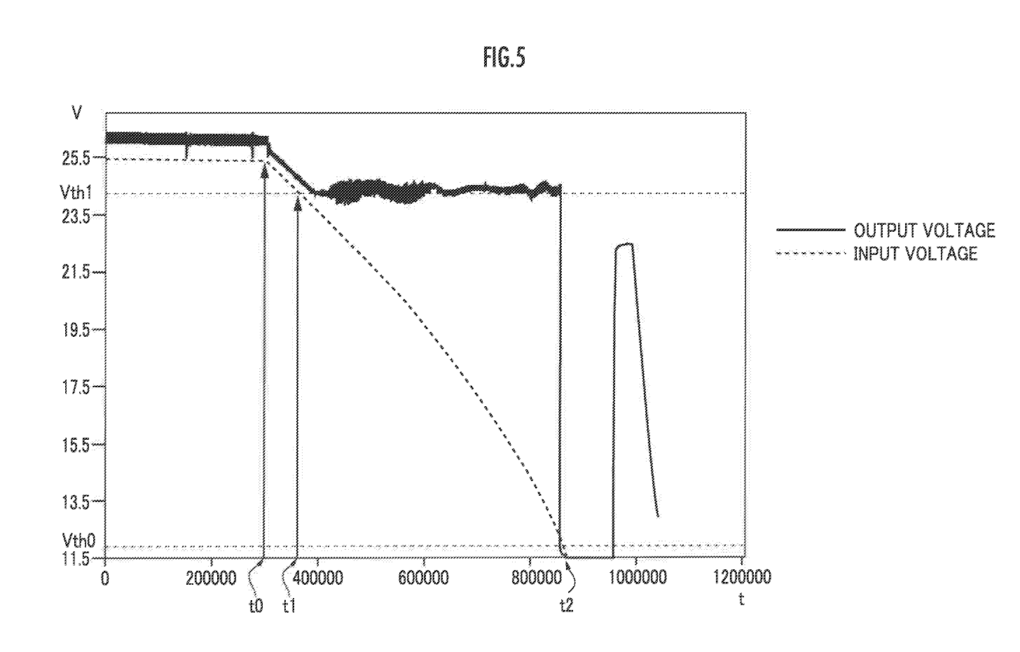

FIG. 5 illustrates an example of the temporal changes in the capacitor voltage V₁ and the output voltage of the converter 12 by the dashed line and the solid line, respectively. In a period from t₀ to t₁, the capacitor voltage V₁ is equal to or higher than the first reference voltage Vₜₕ₁, so that the first drive mode is selected as the electric power control mode, and the output voltage decreases as the capacitor voltage V₁ decreases (refer to YES in STEP12→STEP14 of FIG. 2). In a period from t₁ to t₂, the capacitor voltage V₁ is lower than the first reference voltage Vₜₕ₁ but equal to or higher than the stop voltage Vₜₕ₀, so that the second drive mode is selected as the electric power control mode, and the capacitor voltage V₁ decreases, whereas the output voltage is maintained in the vicinity of the first reference voltage Vₜₕ₁ (refer to NO in STEP12→YES in STEP16→STEP18 of FIG. 2). Then, at time t₂, the capacitor voltage V₁ becomes lower than the stop voltage tₜₕ₀, so that the output voltage is controlled to zero (refer to NO in STEP16→END of FIG. 2).

(Electric Power Control in the Regenerative Mode)

If it is determined that the vehicle 1 is in the regenerative braking mode (the electric motor 14 being in the regenerative mode) (2 in STEP02 of FIG. 2), then the measuring element 21 measures the voltage of the converter 12 on the output side as the regenerative voltage V₂ (STEP20 of FIG. 2). For this measurement, the output signals from a second voltage sensor (not illustrated), which outputs signals based on the regenerative voltage V₂, are used.

The determining element 22 determines whether the regenerative voltage V₂ measured by the measuring element 21 is equal to or higher than a second reference voltage Vₜₕ₂ (STEP22 of FIG. 2). The second reference voltage Vₜₕ₂ is set to a voltage required to charge the capacitor 11 or to a value obtained by adding a slight positive value thereto. The second reference voltage Vₜₕ₂ may be set to the same value as that of the first reference voltage Vₜₕ₁ or a different value.

If the determining element 22 determines that the regenerative voltage V₂ is equal to or higher than the second reference voltage Vₜₕ₂ (YES in STEP22 of FIG. 2), then the mode control element 23 supplies regenerative electric power that has not undergone a step-up operation by the converter 12 to the capacitor 11 from the electric motor 14 according to a first regenerative mode (STEP24 of FIG. 2). In this case, in the converter 12, the step-up element 121 is maintained ON, whereas the step-down element 122 is maintained OFF. Hence, current is supplied from the electric motor 14 to the capacitor 11 via the inverter 13 without the regenerative voltage V₂ being boosted. Thus, the discharge capacitance of the capacitor 11 increases and the capacitor voltage V₁ increases.

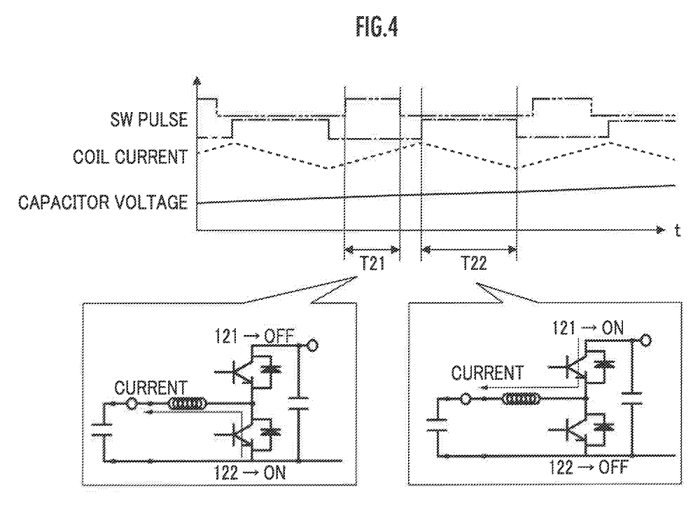

If the determining element 22 determines that the regenerative voltage V₂ is lower than the second reference voltage Vₜₕ₂ (NO in STEP22 of FIG. 2), then the mode control element 23 supplies the regenerative electric power that has undergone the step-up operation by the converter 12 from the electric motor 14 to the capacitor 11 according to a second regenerative mode (STEP28 of FIG. 2). FIG. 4 illustrates an example of how the electric power is controlled at that time. Referring to FIG. 4, the ON/OFF of the step-up element 121 is indicated by the dot-dash line (upper: ON; and lower: OFF), the ON/OFF of the step-down element 122 is indicated by the two-dot chain line, the current passing through the reactor 120 is indicated by the dashed line, and the output voltage on the inverter 13 side is indicated by the solid line, as with FIG. 3.

In a period T₂₁, the step-up element 121 is controlled to OFF and the step-down element 122 is controlled to ON, thereby increasing the current flowing into the reactor 120, so that the current energy accumulated in the reactor 120 increases. In a period T₂₂, which starts after an interval following the period T₂₁, the step-up element 121 is controlled to ON and the step-down element 122 is controlled to OFF, causing the current energy, which has been accumulated in the reactor 120, to be released. This decreases the current flowing into the reactor 120, and the output voltage of the converter 12 on the electric motor 14 side increases. The interval (dead time) between the period. T₂₁ and T₂₂ is set in order to avoid a situation in which the step-up element 121 and the step-down element 122 are both controlled to ON. The repetition of the procedure described above leads to a gradual increase in the output voltage of the converter 12 on the capacitor 11 side, thus causing the capacitor voltage V₁ to gradually increase.

(Effect)

According to the vehicle 1 and the electric power control device 2 as the embodiments of the present invention that exhibit the functions described above, if the capacitor voltage V₁ is equal to or higher than the first reference voltage Vₜₕ₁, then the electric power that has not undergone the step-up operation by the converter 12 is supplied from the capacitor 11 to the electric motor 14, which is the load (refer to YES in STEP12→STEP14 of FIG. 2; and the period from t₀ to t₁ of FIG. 5). Meanwhile, if the discharge capacitance of the capacitor 11 decreases due to the supply of electric power to the electric motor 14, which is the load, causing the capacitor voltage V₁ to decrease below the first reference voltage Vₜₕ₁, then the electric power that has undergone the step-up operation by the converter 12 is supplied from the capacitor 11 to the load (refer to NO in STEP12→STEP18 of FIG. 2; and the period from t₁ to t₂ of FIG. 3 and FIG. 5).

Further, if the regenerative voltage V₂ by the electric motor 14, which is the load, is equal to or higher than the second reference voltage Vₜₕ₂, then the regenerative electric power that has not undergone the step-up operation by the converter 12 is supplied from the electric motor 14 to the capacitor 11 (refer to YES in STEP22→STEP24 of FIG. 2). Meanwhile, if the regenerative voltage V₂ by the electric motor 14, which is the load, is lower than the second reference voltage Vₜₕ₂, then the regenerative electric power that has undergone the step-up operation by the converter 12 is supplied from the electric motor 14 to the capacitor 11 (refer to NO in STEP22→STEP28 of FIG. 2 and FIG. 4).

Thus, the operation duration time of the electric motor 14 and the time during which the power running of the vehicle 1 can be continued are prolonged.

(Other Embodiments of the Present Invention)

In the foregoing embodiment, each of the drive electric power and the regenerative electric power in the vehicle 1 is controlled according to the modes corresponding thereto (one of the first drive mode and the second drive mode, or one of the first regenerative mode and the second regenerative mode). As another embodiment, however, the drive electric power in a different type of equipment from the vehicle 1, such as an industrial or mobile robot or a joint mechanism thereof, may be controlled, or each of the drive electric power and the regenerative electric power may be controlled according to a mode corresponding thereto. In the equipment, if the regenerative braking of the electric motor 14, which is the load, is not involved, then the control of the regenerative electric power (refer to STEPs 20, 22, 24 and 28 of FIG. 2) may be omitted.

In the foregoing embodiment, each of the drive electric power and the regenerative electric power is controlled according to one mode selected from among a plurality of corresponding modes. As another embodiment, however, only one of the drive electric power and the regenerative electric power may be controlled according to one mode selected from among a plurality of corresponding modes.

### DESCRIPTION OF REFERENCE NUMERALS

1 . . . Vehicle (Equipment); 2 . . . Electric power control device; 11 . . . Capacitor; 12 . . . Converter; and 14 . . . Electric motor (Load).

1. An electric power control device for controlling an electric power of a capacitor in equipment provided with a capacitor, a converter, and a load electrically connected, through the converter, to the capacitor serving as a main power supply, the electric power control device comprising:
a measuring element which measures a voltage of the capacitor;
a determining element which determines whether the voltage of the capacitor measured by the measuring element is equal to or higher than a reference voltage required to operate the load; and
a mode control element which supplies electric power that has not undergone a step-up operation by the converter from the capacitor to the load according to a first drive mode in a case where the determining element determines that the voltage of the capacitor is equal to or higher than the reference voltage, and supplies electric power that has undergone the step-up operation by the converter from the capacitor to the load according to a second drive mode in a case where the determining element determines that the voltage of the capacitor is lower than the reference voltage.

2. The electric power control device according to claim 1,
wherein the measuring element measures a regenerative voltage of an electric motor serving as the load,
the determining element determines whether the regenerative voltage of the electric motor measured by the measuring element is equal to or higher than the reference voltage, and
the mode control element supplies regenerative electric power that has not undergone the step-up operation by the converter to the capacitor from the electric motor according to a first regenerative mode in a case where the determining element determines that the regenerative voltage of the electric motor is equal to or higher than the reference voltage, and supplies regenerative electric power that has undergone the step-up operation by the converter to the capacitor from the electric motor according to a second regenerative mode in a case where the determining element determines that the regenerative voltage of the electric motor is lower than the reference voltage.

3. A vehicle comprising: a capacitor; a converter; an electric motor as a load electrically connected through the converter to the capacitor which is a main power supply; and a wheel driven by the electric motor, further comprising,
an electric power control device,
wherein the electric power control device is a device for controlling the electric power of the capacitor in equipment including a capacitor, a converter, and a load electrically connected through the converter to the capacitor which is the main power supply, the electric power control device including:
a measuring element which measures a voltage of the capacitor;
a determining element which determines whether the voltage of the capacitor measured by the measuring element is equal to or higher than a reference voltage required to operate the load; and
a mode control element which supplies electric power that has not undergone a step-up operation by the converter from the capacitor to the load according to a first drive mode in a case where the determining element determines that the voltage of the capacitor is equal to or higher than the reference voltage, and supplies electric power that has undergone the step-up operation by the converter from the capacitor to the load according to a second drive mode in a case where the determining element determines that the voltage of the capacitor is lower than the reference voltage.
